(19) United States
(12) Patent Application Publication
(10) Pub. No.: US 2009/0038829 A1
(43) Pub. Date: Feb. 12, 2009

(54) Printed circut board for population with surface-mounted devices and also method therefor

(76) Inventors: Erik Reischl, Birkenfeld (DE); Peter Leng, Mainz (DE)

Correspondence Address: DELPHI TECHNOLOGIES, INC., M/C 480-410-202, PO BOX 5052, TROY, MI, 48007, US

(21) Appl. No.: 11/811,272

(22) Filed: Jun. 8, 2007

(30) Foreign Application Priority Data
Jul. 7, 2006 (EP) 06014089.4

(51) Int. Cl. H05K 1/03; H01R 43/00

(52) U.S. Cl. 174/255; 29/827

(57) ABSTRACT

A printed circuit board for population with surface-mounted devices is provided simultaneously with a lead frame, which has a three-dimensional shape and which is surrounded by a plastic.

### TECHNICAL FIELD

The invention relates to a printed circuit board for population with surface-mounted devices and a method for populating a printed circuit board, in which surface-mounted devices are mounted on the printed circuit board.

### BACKGROUND OF THE INVENTION

Printed circuits or circuit boards are used in practically every field of technology to control or regulate various devices. Different electrical components, such as integrated circuits, capacitors, resistors, and the like, are arranged on the printed circuit boards, these components being inserted through openings in the printed circuit board and soldered or fused with electrically conductive contacts. Rigid and also flexible printed circuit boards are known to those skilled in the art.

Furthermore, lead frames are known, which are stamped out of metal and with which, for example, the previously mentioned electrical components can be interconnected directly. Such a lead frame is disclosed in DE 44 30 798 A1. This lead frame considerably reduces the expense for connecting different electrical components and can be surrounded with plastic, which is, for example, molded on or in which the lead frame is embedded.

In addition, arranging a miniaturized switch (microcontroller) on a rigid or flexible printed circuit board for regulating or turning on and off an electrical current is known. However, this is disadvantageous to the extent that the switch can switch only a minimal current intensity due to the direct arrangement of the switch next to or on the printed circuit board, because if a larger current flowed through the switch, the switch and/or the printed circuit board could become damaged due to the resulting heat output.

The problem of the invention is to create a printed circuit board of the type named above, which can be populated with different devices, in order to be able to use them in various fields of technology. In addition, In addition, a method for simplified assembly of printed circuit boards is to be specified.

According to the invention, the problem is solved for a printed circuit board, such that a three-dimensional lead frame surrounded by a plastic is arranged on the printed circuit board.

The problem is solved for a method for populating a printed circuit board, in which surface-mounted devices are mounted onto the printed circuit board, according to the invention by simultaneously mounting a three-dimensional lead frame surrounded by a plastic on the printed circuit board.

The central idea of the invention consists in constructing a known lead frame for connecting various electrical components three-dimensionally, so that consequently it does not have a substantially planar construction. In addition, the lead frame is surrounded or enveloped with a suitable plastic material or embedded in such a plastic, in order to obtain additional electrical and for suitable selection of the plastic also thermal isolation. Obviously, possibly necessary contact surfaces or electrically conductive areas, which are to be connected to other components or switches, are not coated with plastic. Corresponding plastics, depending on the selected metal or metal alloy for the lead frame and also the material of the printed circuit board, are known to those skilled in the art.

Such a three-dimensional lead frame coated with a plastic, together with other electrical components, so-called surface-mounted devices, SMD, can be fixed to or on the printed circuit board in one processing step. For this purpose, the three-dimensional lead frame is positioned by machine on the printed circuit board and soldered or fused in place in the same way and in the same processing step as other surface-mounted electrical devices. Thus, the fabrication process for a printed circuit board is simplified considerably, because different electrical components and also lead frames can be mounted simultaneously.

Obviously, printed circuit boards provided with additional lead frames can be used in all fields of technology, for example, in mechatronics, in order to be able to switch currents with switches on a rigid or flexible printed circuit board, wherein the printed circuit board can be fabricated using MID technology (molded interconnected device). It may also involve a three-dimensional plastic part with conductor tracks.

### SUMMARY OF THE INVENTION

Preferably, the three-dimensional lead frame has a shell-like structure, in order to have essentially the same construction as other surface-mounted devices and thus to simplify the fabrication or mounting process. Furthermore, with such a lead frame, another electrical component, as described below, is fixed to this lead frame at a distance from the printed circuit board itself, which would reliably prevent, in particular, thermal or switching-specific damage to the printed circuit board.

Advantageously, a contact surface, which is designed, in particular, such that an electrical connection can be produced via a moving contact slide, wherein the contact slide is positioned such that it can be brought into contact with the contact surface. In particular, such a contact surface can be provided with a coating for improving the contact with other electrical components.

In another construction, the lead frame is designed such that it can be loaded with currents of higher current intensity. In particular, it can be constructed in a corresponding thickness or with corresponding cross sections, wherein the three-dimensional construction of the lead frame guarantees that the currents flowing through the lead frame do not lead to thermal damage to the rigid or flexible printed circuit board.

According to one refinement, the lead frame is limited by guide elements for a slide switching element. Preferably, in particular, integrally formed ramps are associated with the guide elements, these ramps interacting with contact arms for lifting off and touching down on contact surfaces. Alternatively, the lead frame carries plug contacts in a plug collar. Preferably, the guide elements and/or the plug collars are produced from plastic and formed integrally with the printed circuit board.

In addition, other surface-mounted devices can be arranged and/or contacted on the shell-like lead frame, in order to distance these components from the printed circuit board via the lead frame. These components can be mounted simultaneously or in a different processing step.

The printed circuit board has either a rigid or a flexible construction. A rigid printed circuit board consists essentially of a perforated plastic plate, with the various electrical components or lead frames being inserted with their electrical contacts into the holes and soldered or fused in place. A flexible printed circuit board consists of a suitable, permanently flexible plastic material.

For improving the electrical contact, a contact surface of the lead frame is preferably provided with an additional coating to improve the contact with a previously mentioned moving contact slide. In particular, a silver-nickel-20 alloy, which is known to those skilled in the art, is suitable for such a coating. The application of this coating is possible for a three-dimensional lead frame without damaging the printed circuit board.

It is understood that the features named above and still to be explained below can be used not only in the specified combination, but also in other combinations. The scope of the invention is defined only by the claims.

### BRIEF DESCRIPTION OF THE DRAWINGS

The invention is explained in more detail below using two embodiments with reference to the associated drawings. These show:

FIG. 1 a printed circuit board from the state of the art,

FIG. 2 a printed circuit board according to the invention with embedded lead frame, and

FIG. 3 a printed circuit board from FIG. 2 in an alternative construction.

### DESCRIPTION OF THE PREFERRED EMBODIMENTS

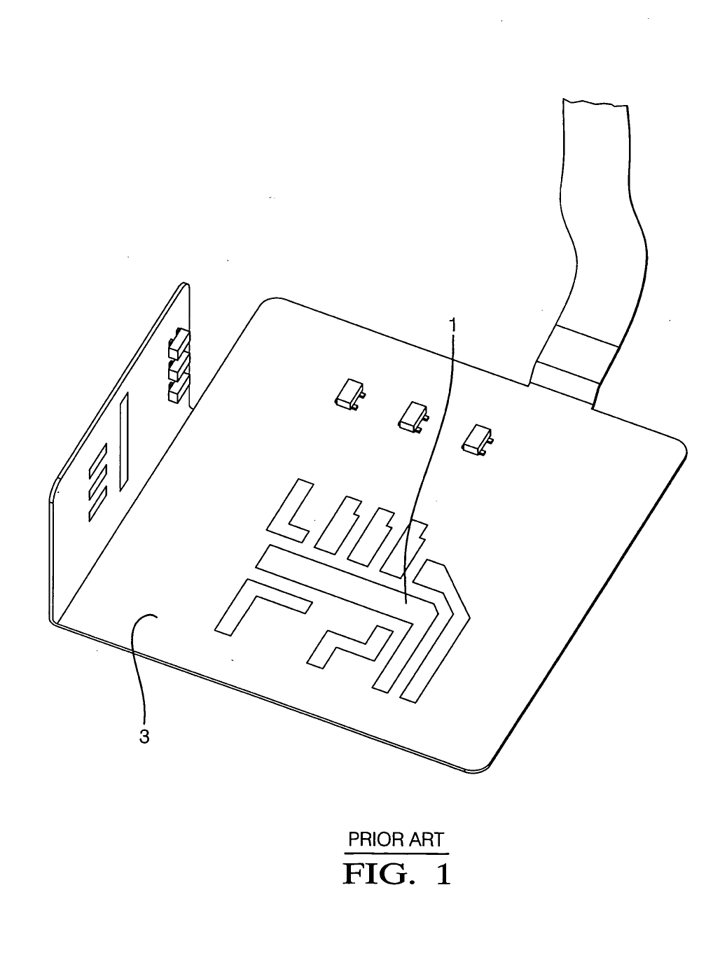

The printed circuit board 3 from FIG. 1, which has either a rigid or flexible construction, represents a known printed circuit, in which various electrical components, such as integrated circuits, capacitors, and resistors, are placed and soldered or fused in a typical way onto a rigid plastic board. On the printed circuit board 3 there is a lead frame 1 for making contacts for various electrical components, wherein the current intensity of the currents flowing through the lead frame 1 is limited by the substantially planar construction of the lead frame 1, because otherwise thermal damage to the printed circuit board 3 due to the released electrical power could not be avoided.

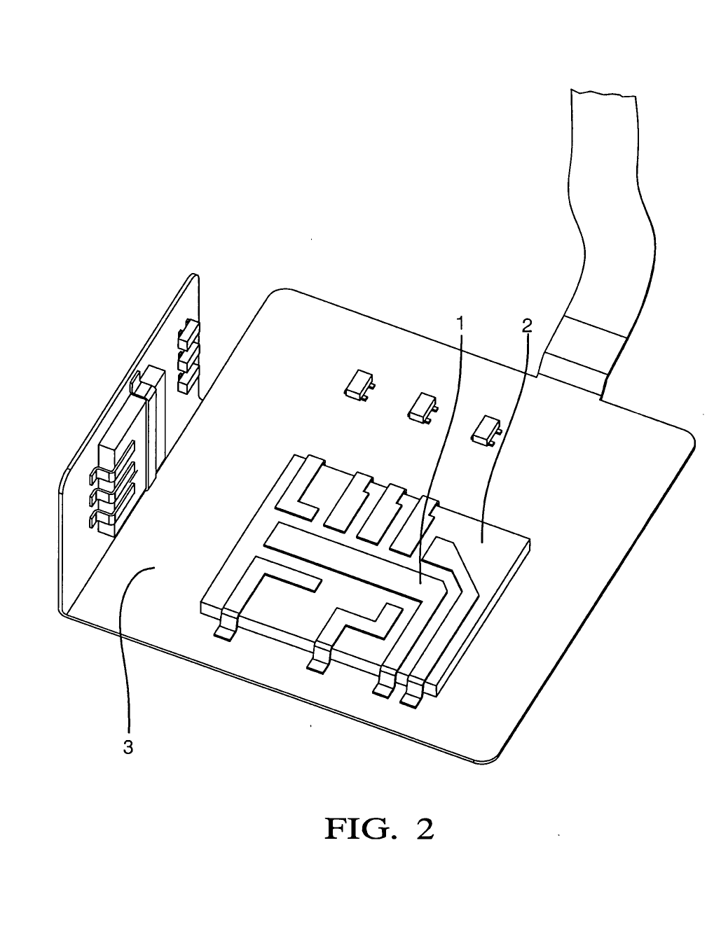

According to FIG. 2, the lead frame 1 is embedded in a suitable plastic 2 and has a shell-like or three-dimensional construction, in order to allow higher current intensities to flow. In particular, such a lead frame 1 can be arranged together with other electrical components 5 and soldered or fused in a single processing step, whereby the production of such a printed circuit board 3 is considerably simplified.

Furthermore, other surface-mounted electrical components can be arranged on the shell-like lead frame 1, in order, among other things, to thermally isolate these components from the printed circuit board 3.

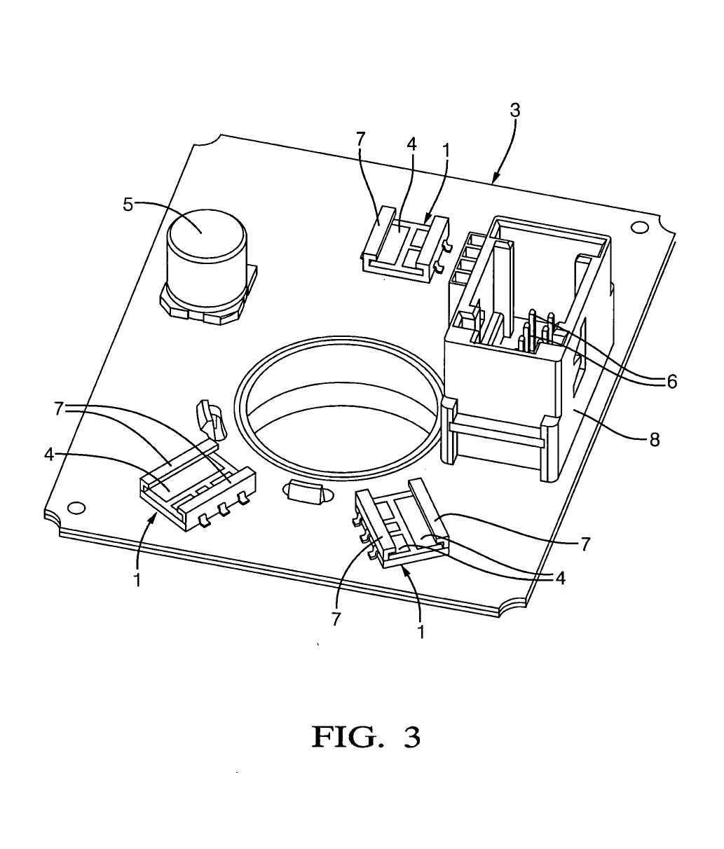

From FIG. 3, several lead frames 1 with contact surfaces 4 and a lead frame 1 with contact pins 6 are connected integrally to a printed circuit board 3 carrying an electrical component 5. Each lead frame 1 with contact surfaces 4 is connected on both sides by guide elements 7 made from a plastic connected integrally to the printed circuit board 3 for movable support of a slide switching element, which acts on the contact surfaces 4 with its spring-loaded contact arms. A plug collar 8, which is produced just like the guide elements 7 from a plastic, is allocated to the lead frame 1 with contact pins 6.

1. A printed circuit board for population with surface-mounted devices, comprising a three-dimensional lead frame surrounded by an electrical insulator arranged on the printed circuit board.

2. The printed circuit board of claim 1, wherein the lead frame has a shell-like construction.

3. The printed circuit board of claim 1, wherein a contact surface is constructed on one surface of the lead frame.

4. The printed circuit board of claim 3, wherein the contact surface is coated.

5. The printed circuit board of claim 1, wherein the lead frame can be loaded with currents of high current intensity.

6. The printed circuit board of claim 1, wherein the lead frame is limited by guide elements for a slide switching element.

7. The printed circuit board of claim 6, wherein integrally formed ramps are associated with the guide elements, said ramps interacting with spring-loaded contact arms for lifting off of and touching down on the contact surfaces.

8. The printed circuit board of claim 1, wherein the lead frame carries contact pins arranged in a plug collar.

9. The printed circuit board of claim 6, wherein the guide elements and/or the plug collars are made from plastic and constructed integrally with the printed circuit board.

10. The printed circuit board of claim 1, further comprising surface-mounted device can be fixed to the lead frame.

11. The printed circuit board of claim 1, wherein the printed circuit board has a rigid or flexible construction.

12. A method for assembling a printed circuit board, in which surface-mounted devices are attached to the printed circuit board, wherein a lead frame, which is at least partially surrounded by plastic and which has a three-dimensional construction, is fixed simultaneously to the printed circuit board.

13. The method of claim 12, wherein a coating, especially a silver-nickel-20 alloy, is provided for a contact surface of the lead frame.

14. The method of claim 12, wherein another surface-mounted device is fixed to a contact surface of the lead frame.

15. An electrical assembly comprising:
a printed circuit board defining a generally planer surface for carrying surface mounted electrical devices as part of a circuit assembly;
a three-dimensional lead frame having a first portion affixed to said printed circuit board surface to establish electrically conductive paths therebetween and a second portion spaced from said printed circuit board to define at least one contact surface;
an electrical insulator supportingly disposed between said printed circuit board surface and the second portion of said lead frame; and
a plurality of extensions integrally formed with said electrical insulator to define cooperating opposed guide surfaces adjacent said at least one contact surface, said guide surfaces operative to position a spring-loaded contact arm in register with said at least one contact surface.
